(19) United States
(12) Patent Application Publication
(10) Pub. No.: US 2013/0214134 A1
(43) Pub. Date: Aug. 22, 2013

(54) PHOTON DETECTOR

(71) Applicants: Oliver Edward Thomas, Cambridgeshire (GB); Zhiliang Yuan, Cambridgeshire (GB); Andrew James Shields, Cambridgeshire (GB)

(72) Inventors: Oliver Edward Thomas, Cambridgeshire (GB); Zhiliang Yuan, Cambridgeshire (GB); Andrew James Shields, Cambridgeshire (GB)

(73) Assignee: Kabushiki Kaisha Toshiba, Tokyo (JP)

(21) Appl. No.: 13/504,798

(22) PCT Filed: Nov. 11, 2011
(86) PCT No.: PCT/GB2011/001595

§ 371 Date: Nov. 5, 2012

(30) Foreign Application Priority Data
Nov. 12, 2010 (GB) 1019217.7

(51) Int. Cl. H01L 31/107

(52) U.S. Cl. CPC H01L 31/107
USPC 250/214 R; 257/438

(57) ABSTRACT

A photon detection system comprising an avalanche photo-diode, said avalanche photodiode comprising a p-n junction formed from a first semiconductor layer having a first conductivity type and a second semiconductor layer having a second conductivity type, wherein the first conductivity type is one selected from n-type or p-type and the second conductivity type is different to the first conductivity type and is selected from n-type or p-type, wherein the first semiconductor layer is a doped layer which is doped with dopants of a first conductivity type and where there is a variation in the concentration of dopants of the first conductivity type such that the first layer comprises islands of high field zones surrounded by low field zones, the high and low field zones distributed laterally in the plane of the p-n junction, wherein the dopant concentration is higher in the high field zones than the low field zones, said system further comprising a biasing unit, said biasing unit being configured to apply a voltage which is static in time and a time varying voltage.

Embodiments described herein generally relate to photon detectors and methods for detecting weak light signals.

There is a pressing need in a number of applications for optical light detectors which can register a response at the level of individual photons. Single photon detectors are threshold devices which detect the presence of 1 or more photons on the device, but cannot determine the number of photons. They are used for general low light level detection, as well as for various applications based around determining the arrival time of the photon at the detector.

The applications of single photon detectors include industrial inspection, environmental monitoring, testing of fibre optic cables and components, medical imaging, chemical analysis and scientific research. Many of these applications use the ability of a single photon detector to measure the arrival time of a single photon. In industrial inspection systems a bright laser pulse is directed at the object under inspection and the time for single photons from the pulse to be reflected are recorded. From the time of flight data it is possible to build a 3D image of the object. Similar techniques involving single photon detectors are used to determine the location of faults in optical fibres and components, and to measure particles in the atmosphere.

Single photon detection is also used in various forms of x-ray and radioisotrope imaging in medical imaging, as well as in laser optical imaging at infra-red wavelengths. Lifetime fluorescence measurements using single photon detection can be used in the diagnosis of some medical conditions. It is employed in analytical chemistry for determining the chemical recipe of a sample. Single photon detection is also used in scientific research in the field of particle physics, astrophysics and materials science.

Photon number resolving detectors, not only detect the presence of photons, but are able also to count the number of photons in an incident light pulse. Like single photon detectors they are able to determine the arrival time of the photons at the detector.

Photon number resolving detectors are required for low noise light detection based on photon counting. Here they have the advantage over single photon detectors that they can operate with higher light intensities.

The ability to resolve the number of photons in the incident pulse is also very important for many applications in quantum information technology. In a quantum relay, for example, it is necessary to distinguish between 0-, 1- and 2-photon detection events in each detector. A similar detector capability is needed for many of the gates used in linear optics quantum computing.

A photon number resolving detector which can operate at visible/near infra-red wavelengths (300-1100 nm) has applications for linear optics quantum computing, quantum relays and repeaters, quantum cryptography, photon number state generation and conditioning, and characterisation of photon emission statistics of light sources.

Currently Geiger Mode Silicon Avalanche Photodiodes (APDs) are used for low noise light detection at visible/near infra-red wavelengths (300-1100 nm).

The present invention will now be described with reference to the following non-limiting embodiments in which:

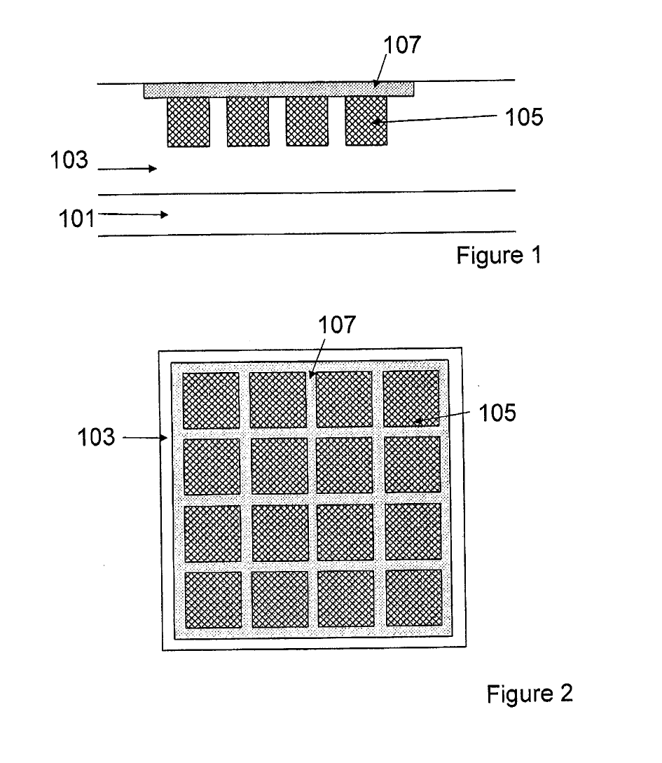

FIG. 1 is a cross-section of a photon detection system in accordance with an embodiment of the present invention;

FIG. 2 shows a plan view of the system of FIG. 1;

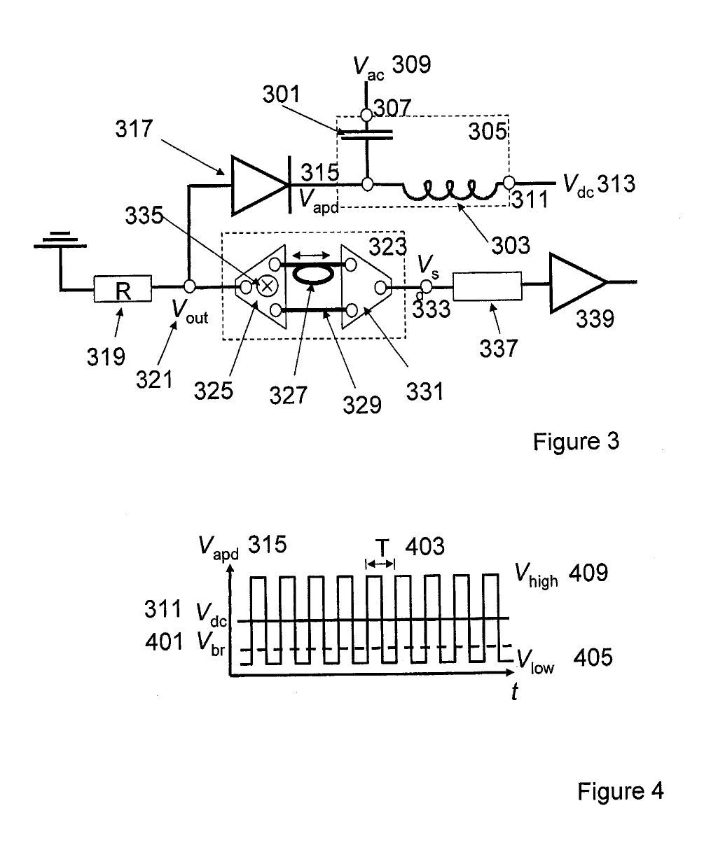

FIG. 3 shows a biasing circuit used for biasing the structure described with reference to FIGS. 1 and 2;

FIG. 4 is a plot of APD bias over time for the detection system described with reference to FIGS. 1 to 3;

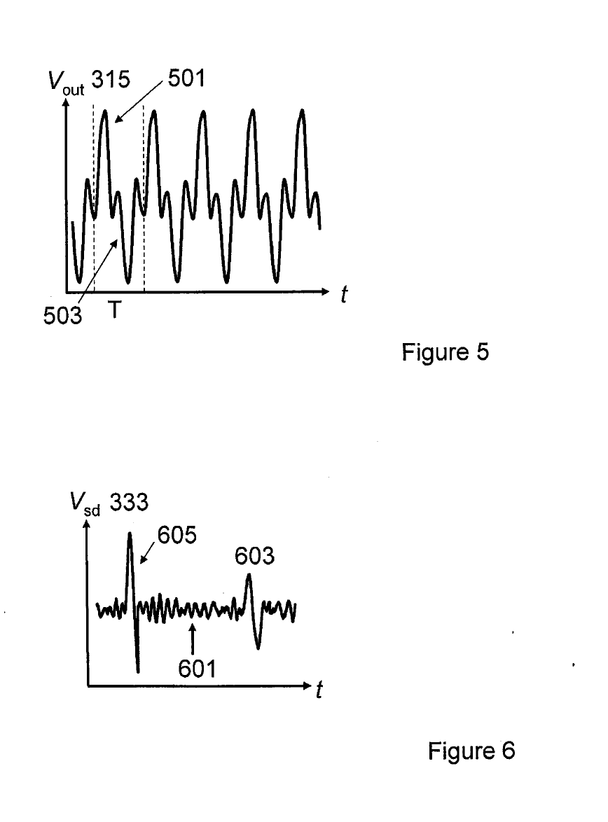

FIG. 5 is a plot of the output bias of the device of FIGS. 1 to 3 over time;

FIG. 6 is a schematic of an output voltage over time after the output has been self differenced using the circuit of FIG. 3;

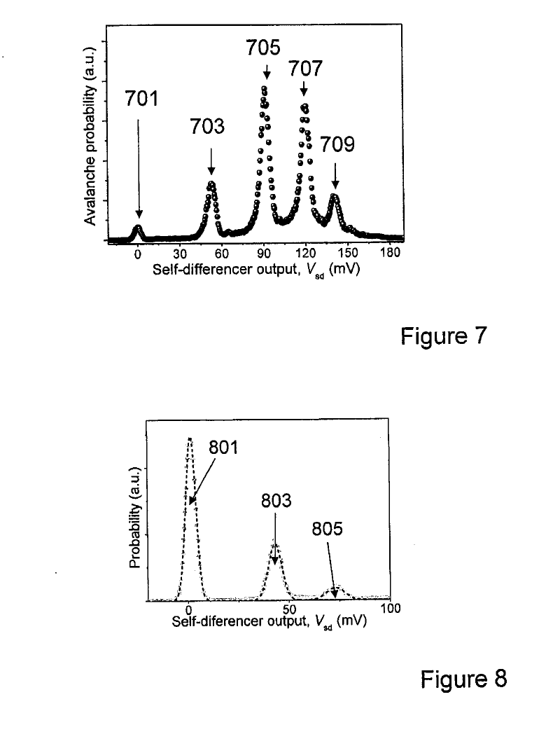

FIG. 7 is a plot of the probability distribution as a function of the self differenced output;

FIG. 8 is a schematic of the measure probability distribution of the output signal;

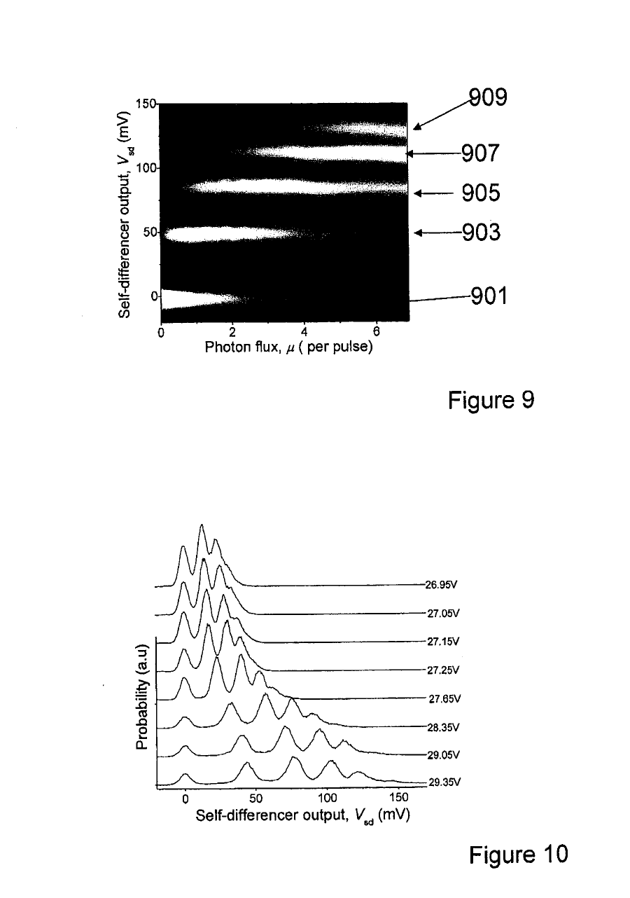

FIG. 9 is a grey scale showing the dependants of the output and its dependence on photon flux;

FIG. 10 is a plot of the probability distribution for a fixed incident photon flux as a function of the applied DC biases;

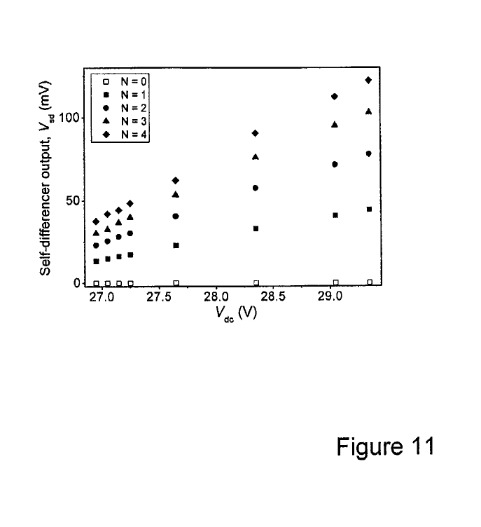

FIG. 11 is a plot of the mean voltages of the 0, 1, 2, 3 and 4 photon peaks has a function of the applied DC bias;

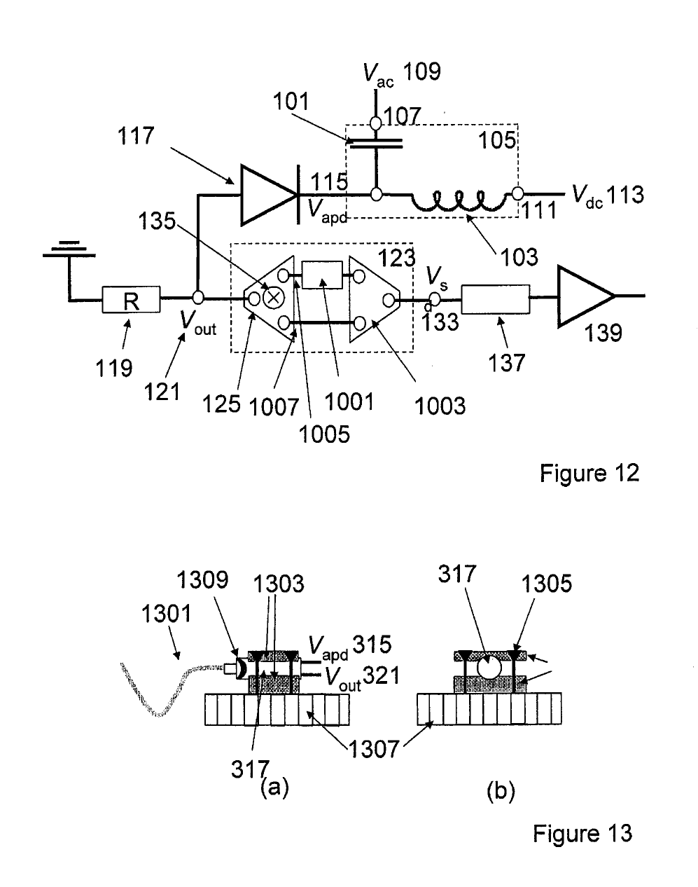

FIG. 12 shows a system in accordance with a further embodiment of the present invention; and

FIGS. 13a and 13b show two views of a system in accordance with a further embodiment of the present invention.

According to an embodiment a photon detection system is provided comprising a photon detection system comprising an avalanche photo-diode, said avalanche photodiode comprising a p-n junction formed from a first semiconductor layer having a first conductivity type and a second semiconductor layer having a second conductivity type, wherein the first conductivity type is one selected from n-type or p-type and the second conductivity type is different to the first conductivity type and is selected from n-type or p-type, wherein the first semiconductor layer is a doped layer which is doped with dopants of a first conductivity type and where there is a variation in the concentration of dopants of the first conductivity type such that the first layer comprises islands of high field zones surrounded by low field zones, the high and low field zones distributed laterally in the plane of the p-n junction, wherein the dopant concentration is higher in the high field zones than the low field zones, said system further comprising a biasing unit, said biasing unit being configured to apply a voltage which is static in time and a time varying voltage.

In one embodiment, the second layer covers both high and low field zones. In a further embodiment, the second layer just covers the high field zones such that a pn-junction is only formed with the high field zones.

In one embodiment, the high field zones have a geometric filling factor of 0.5 or more of the whole area of the avalanche photodiode. In a yet further embodiment, the geometric filling factor is 0.8 or more. The whole area being the high field zone areas and the areas between high field zone areas.

In one embodiment, the shortest distance between adjacent high field zones is 5 μm or less.

In the arrangements in accordance with embodiments to the present invention, the high field zones are coupled electrically through the second semiconductor layer. Also, in one embodiment, the low field zones have a uniform electrical potential or have a uniform doping concentration.

In one embodiment, the high field zones are identical in lateral size and shape.

Embodiments of the present invention are used for counting the number of photons incident on the avalanche photodiode in a single pulse of radiation. When a pulse of radiation is incident on the avalanche photodiode, an avalanche effect is experienced in the high field zones of the photodiode. In one embodiment, the system further comprises a counting circuit for measuring the avalanche event in order to determine the number of photons in the received photon pulse. This counting circuit may measure the size of a signal caused due to the avalanche effect, in another embodiment, it counts the number of reset pulses as described in GB2469961 and GB2447054 herein incorporated by reference.

In a further embodiment, the counting circuit comprises a discriminator configured to compare the measurement of the avalanche event with multiple predetermined levels.

In a further embodiment, the system further comprises an output circuit configured to receive an output signal from said avalanche photodiode and to process the output signal to remove a time variant component from the output signal. For example, if the time varying component is cyclical, the output circuit maybe configured to compare the output voltage of the avalanche photodiode in one cycle with that of the preceding cycle. Photon detectors with output circuits for processing the output from an APD are described in U.S. Ser. No. 12/529,495, GB2466299 as herein incorporated by reference.

In a further embodiment, the output circuit comprises a signal divider to split the output signal into two parts an electrical line to delay one of the parts relative to the other and a signal difference to output the difference between the two parts. This allows the cyclical background signal to be cancelled to leave the signal due to the detected photons.

In a further embodiment, the output circuit is configured to combine the output voltage of the APD in the first and second half of the gating biasing period. In a further embodiment, the delay has an integer number of gate periods. The electrical circuit may also comprise a phase shifter in addition to the signal divider in order to shift the phase of one of the two parts of the signal by 180°. A signal inverter may also be provided to perform the same function. A signal combiner is then provided to output the sum of the two parts.

The period of the cycle of the time varying bias may be fixed but in other embodiments, it may vary as a function of time. By causing a jitter in the length of the period, the detection system can adopt a quasi CW type of operation.

In a further embodiment, a controller is provided to balance the strength of the two parts. A controller may also be configured to vary the length of the delay to allow tuning of the detection system in-situ.

In a further embodiment, the output circuit comprises a band rejection filter in order to isolate the signal due to the avalanche.

In one embodiment, the biasing circuit is configured to apply a time varying component which has two levels, a high level and a low level. In a further embodiment, the duration of the higher level part of the voltage component is short enough to prevent the avalanche current of the whole device saturating. In another embodiment, there is a high part of the time varying component which is above the breakdown voltage and a lower part which is below the breakdown of the avalanche photodiode. The form of the bias may be a sine wave, square wave etc.

In a further embodiment, a lens and collimation optics are provided to disperse the incident light uniformly across the active area of the avalanche photodiode. In a yet further embodiment, a microlens array or binary diffractive beamsplitter is used to illuminate just the high electric field zones by means of structured, multi-spot illumination.

A method of fabricating a photon detection system is provided according to a further embodiment, the method comprising: forming a p-n junction by: forming a first semiconductor layer having a first conductivity type, wherein the first semiconductor layer is a doped layer which is doped with dopants of a first conductivity type and where there is a variation in the concentration of dopants of the first conductivity type such that the first layer comprises islands of high field zones surrounded by low field zones, wherein the dopant concentration is higher in the high field zones than the low field zones, the high and low field zones distributed laterally in the plane of the p-n junction; and forming a second single semiconductor layer having a second conductivity type in contact with the first semiconductor layer, the first conductivity type is one selected from n-type or p-type and the second conductivity type is different to the first conductivity type and is selected from n-type or p-type, the method further comprising applying a voltage which is static in time and a time varying voltage across the p-n junction.

In one embodiment, forming the first semiconductor layer comprises forming high field zones using gas emersion laser doping, implantation or diffusion to embed material with a higher dopant concentration into material with a lower dopant concentration. Thus, regions of highly doped material are formed surrounded by regions of lower doped material.

In a further embodiment, the first semiconductor layer is etched to form pits in said layer and material with a higher doping concentration of the same conductivity type is provided in said pits.

FIG. 1 is a schematic cross-sectional view of an avalanche photodiode (APD) which is to be used in a system in accordance with an embodiment of the invention.

The APD comprises a layer of a first conductivity type 103 and a layer of a second conductivity type 107 overlying and in contact with the layer of the first conductivity type 103. In this particular embodiment, the layer of the first conductivity type 103 is overlying and in contact with a substrate 101. In this particular embodiment, the layer of the first conductivity type 103 is a p-type layer and the layer of the second conductivity type 107 is an n-type layer. However, it will be appreciated that the order of the layers could be changed. A p-n junction is formed at the interface between the first layer 103 and the second layer 107.

The first layer 103 comprises regions 105 which have a higher dopant concentration than the remainder of the layer 103. These regions will be formed as islands so that they are laterally separated from other high dopant concentration regions. For the avoidance of doubt, the term “high dopant concentration region” refers to the concentration of the carriers donated by the dopant and not necessarily the concentration of the dopant itself. It will be appreciated by those skilled in the art, that a dopant that donates two carriers may be provided in a slightly lower concentration than a dopant that contributes one carrier and still provides a higher carrier concentration.

The fabrication of the structure of FIG. 1 will now be described.

The basis for the heterostructure is a p-type substrate 101, on which the subsequent layer structure is fabricated. A uniform p-type heterolayer 103 is deposited on said substrate 101. Areas of highly-doped p-type material 105 are incorporated into said layer 103. Said areas may be incorporated, for example by Gas Immersion Laser doping, ion implantation or drive-in diffusion.

A layer of highly-doped n-type material 107 is subsequently grown across an area to encompass all of the highly-doped p-type regions 105, for example by Gas Immersion Laser doping, implantation or diffusion.

A high electric field is generated across the interface between the highly doped p-type islands 105 and the n-type material in these regions, in which avalanche multiplication can occur when a suitable bias is applied across the junction. These regions 105 therefore constitute active zones of the device which are sensitive to single photons. This is in contrast to the low-electric field which is formed between the moderately doped p-type layer 103 and the n-doped layer 107, which is not sufficient to support avalanching and therefore acts as an optically inactive spacer between the active zones when operated in the Geiger mode which will be described later. The depth of the highly-doped layers 105 and 107 can be less that 4 μm such that a thin junction with a shallow depletion region is achieved, with the APD having a corresponding low breakdown voltage. The junction depth may also be larger than this, for example 30 μm or above, such that a deep junction device is satisfied with a large breakdown voltage.

These areas 105 and the adjoining n-type layer form the active avalanche regions of the device and the size, geometry and arrangement of these regions, in relation to the intermediate low-field regions, can be controlled by manipulating the 2-D doping profile in the plane of the p-n junction according to the requirements of the application. The number of photons that can be detected and discerned is fixed by the number of these active zones and the detection efficiency has a dependence on the geometrical fill-factor.

In an embodiment, the active zones are pixels. In one embodiment, the maximum number of photons for which the detected signal is linear with the incident signal is N/2, where N is the number of pixels. For incident photon numbers exceeding this figure, there is a greater probability of multi-photon absorption within a single pixel and subsequently there will be errors in the detected photon number distributions. Therefore, the higher the number of high-field ‘pixels’, the higher the number of photons that can be detected without error.

The fill-factor can be regarded as the ratio of the area of high-field regions to the total device area, i.e. a high fill-factor implies a high density of high-field zones. The detection efficiency increases with the fill-factor to reflect the increased probability of a photon being incident upon a high-field pixel which is single-photon-sensitive.

In an embodiment the first 103 and second 105 layers may be silicon, in which p-type and n-type doping may be achieved using Boron or Phosphorous impurities respectively. It may also be a Silicon—Germanium heterostructure or based on the III-V class of semiconductors such as InGaAs among others.

In one embodiment, photon absorption takes place within the APD in a layer with an energy bandgap larger than 400 meV.

In a further embodiment, the APD has a total area of 10 to 200 microns with a geometrical fill factor of the active high-field zones 105 of 0.8 or more. In one embodiment, the junction capacitance is 10 pF or less.

In another embodiment, the APD is fabricated on an n-doped substrate 101 and comprises highly n-doped regions 105 which are incorporated into a moderately doped n-type heterolayer 103, for example by Gas Immersion Laser doping, implantation or diffusion. The active regions are then formed by a layer of highly doped p-type material 107, which is incorporated by ion implantation or diffusion as before. This may be achieved with the material systems mentioned above.

FIG. 2 shows the corresponding plan view of the APD of FIG. 1, comprising part of the invention, in which the active regions formed by the semiconductor junction between highly doped p-type 105 and n-type 107 layers are arranged in a matrix configuration.

The highly doped regions 105 form islands. The arrangement shown would allow discrimination between optical pulses containing up to 16 photons and preferably the device would consist of 4-1000 single photon-sensitive active zones, depending on the application. In an embodiment, the highly doped regions are from 5 to 50 μm in width and are separated by less than 5 μm. The high field zones can in principle be any shape, including polygonal and circular, with the overall geometry being matched to the intensity and beam profile of the illumination source.

In an embodiment, the high field zones will have a doping concentration of at least 10¹⁰ cm⁻², in a further embodiment at least 10¹¹ cm⁻² or 10¹² cm⁻². The doping concentration of the lower field zones being at least a factor of 10 lower than that for the high field zones, in a further embodiment a factor of 100 lower.

FIG. 3 shows a system in accordance with an embodiment of the present invention using the APD of FIGS. 1 and 2.

The APD is arranged in a configuration which allows self-differencing of the output signal. In a self differencing mode of operation, the background of the output signal is removed by comparing a part of the signal with an earlier part of the signal.

The APD 317 is connected such that it is reverse biased. The bias voltage comprises both a DC component V_{DC} 311 from DC bias source 313 and an AC component V_{AC} 307 from AC bias source 309.

The AC 307 and DC 311 components are combined using bias-tee 305. Bias tee 305 comprises, on a first arm of the tee, a capacitor 301 connected to the AC source 309 and, on the second arm of the tee, an inductor 303 connected to the DC source 313.

The output of the APD 317 is divided between a resistor 319 (which leads to ground) and self differencing circuit 323.

When a photon is incident on APD 317, an avalanche photocurrent is induced by an avalanche arising from photon detection which leads to a voltage across a series resistor 319, which corresponds to the output voltage, Vₒᵤₜ, 321.

To isolate the periodic capacitive response of the APD 317 to a gating modulation, which masks small avalanches resulting from high-speed operation, a self-differencing circuit is used 323, comprising a signal divider 325, two electrical lines 327 and 329 and a signal differencer 331.

The APD output voltage, Vₒᵤₜ, 321 is input into signal divider 325, which divides the signal into two close to equal components. A potentiometer 335 is used to balance the dividing ratio and further equate the two components. Since one of the electrical lines 327 is longer than the other 329, one of these components is delayed.

The delay is chosen to be an integer number of gating periods T supplied by the AC voltage source 311, and the delay line 327 is chosen to be adjustable in order to tune the delay independently of T.

When these two signals are input into the signal differencer 331, they are subtracted one from the other and the strong periodic capacitive background is largely cancelled in the self-differencer output voltage, V_{sd}, 333. A 780 MHz low-pass filter 337 and amplifier 339 may be used to further improve the retardation of the capacitive background. Alternatively, filter 337 can be replaced by a tuneable band pass filter to exclude frequencies associated with the uncancelled signal.

This allows small unsaturated avalanche-related voltage signals to be revealed in the self-differencer output, V_{sd}, 133. The amplitude of these small signals is dependent upon the incident photon number, according to the number of high-field pixels that are stimulated. The output signal will comprise the sum of the quasi-saturated signals arising in multiple stimulated pixels.

As an alternative to the set-up in FIG. 3, the electrical delay between the electrical lines 327 and 329 may be chosen to be an odd integer number of half the gating period T.

In this case the signal differencer 331 is replaced by a signal combiner, which adds the two signals. This also has the effect of cancelling the capacitive response of the APD 317 leaving only the weak photon induced avalanche signal.

In a further embodiment, a band rejection filter may be used to exclude the oscillatory part of the detector voltage response.

If devices in accordance with an embodiment of the present invention were used in the conventional Geiger mode, they would behave as a large area photon detector which will not discriminate between the absorption of one or more photons due to the saturated photocurrent.

In the above embodiment, the bias is above the breakdown voltage for a time which is sufficiently short so as to prevent the total device current from saturating, such that each high field pixel 105 is stimulated into a single photon sensitive state during each voltage cycle. However, the time for which the bias is above the breakdown voltage may be sufficient to effectively saturate the avalanche photocurrent induced in each high field pixel 105. The individual quasi-saturated avalanche photocurrent signals from multiple pixels are then summed by the device in order to reflect the number of stimulated pixels. This summation is manifested due to the common contact layer 107 which electrically couples the high field zones 105 in parallel.

In an embodiment, it is presumed that each pixel will detect at most one photon in each cycle. Multi-photon detection therefore occurs due to photons being received at multiple pixels and the summation of the output from the different pixels. In an example of such an embodiment it is assumed that the within a single pixel, the signal due to photon absorption is quasi-saturated.

In a further embodiment, the detector is configured such that the number of photons arriving at each pixel can be determined. In a further example of such an arrangement, it is assumed that within a single pixel the signal increases linearly with the absorbed sub-pixel photon number (i.e. a multiple of the single photon signal) instead of the photon signal being quasi-saturated.

FIG. 4 shows a bias conditions which may be used to obtain high single photon detection efficiency and photon number resolution from an APD in accordance with an embodiment of the present invention.

The APD has a reverse breakdown voltage V_{br} 401 above which a macroscopic avalanche gain of photoexcited carriers can occur.

The APD bias voltage V_{apd} 315, comprises a DC voltage V_{dc} 311 superimposed on a AC voltage with peak-to-peak amplitude V_{ac} 307 and a period T 403. The period of the AC bias is sometimes referred to as the gating period or the clock period and is the inverse of the gating frequency or clock frequency.

The gating period or clock period may be synchronised with that of a photon source.

In one embodiment the gating frequency of the detector is varied by a small amount e.g. 50 kHz, which is used to essentially broaden the time window over which the detector is capable of detecting photons.

This results in the APD bias voltage 315, lying above the breakdown voltage 401 at its highest values V_{high} 209 and below the breakdown voltage 401 at its lowest values V_{low} 205. V_{dc} can also be set below the breakdown voltage.

It has been found experimentally that in an embodiment where the APD is silicon based, the DC bias, V_{dc}, 311 may be larger in magnitude than the reverse breakdown voltage, V_{br} 401.

The APD may be operated with an AC gating period of 1 ns, corresponding to a gating frequency of 1 GHz.

Depending on the operation temperature and the actual device structures, the breakdown voltage for APDs can vary from 20 to 300 V. (Note this is written as a positive number, although it is actually a reverse bias applied to the p-n junction of the APD).

The APD may be operated with a DC bias V_{dc} of 29.35 Volts and an AC voltage peak to peak amplitude of V_{ac}=7.0 V.

FIG. 5 shows the measured electrical response of an APD based on silicon, Vₒᵤₜ, 321 to the circuit and bias conditions V_{apd} 315 described above.

The strong oscillatory signal observed in Vₒᵤₜ 321 is due to the capacitive response of the APD 317 to the applied AC voltage Vac 307.

These strong oscillations conceal any contribution to the signal from avalanches stimulated by photons absorbed in the APD 317.

A positive peak 501 is due to the charging of the APD capacitance when reacting to the leading edge of the AC bias 307, followed by a negative peak 503 corresponding to the capacitive discharging arising from the falling edge of the AC bias 307.

Clearly these very strong oscillations due to the capacitive response of the APD, mean that it is usually not desirable to operate APDs in gated Geiger Mode for single photon detection.

FIG. 6 shows the measured self-differencer output, V_{sd}, 133 for one photon 603, two photons 605 and no detected photons 601, sampled using a fast digital oscilloscope.

Note that the 0-photon signal 601 has finite amplitude due to the imperfect cancellation of the self-differencing circuit.

The 2-photon peak 605 has approximately double the amplitude of the 1-photon peak 603, indicating that there is approximately linear dependence of the output voltage, V_{sd}, 333 on the detected photon number for low numbers of photons N. This is due to the fact that multi-photon signals arise from the summation of avalanches detected in each highly doped region 105.

This proves that the detector works as a photon number resolving detector.

In the APD used in a system in accordance with the above embodiment, both a DC voltage source and AC voltage source are also used to provide an alternating bias that periodically biases the APD above and below its breakdown voltage.

In the above described APD, the lateral electric field profile of the APD light-sensitive area is strongly modified in order to produce a single mesa diode structure consisting of many high electric field zones (highly doped regions), separated by areas of lower electric field (lower doped regions). This can be achieved using a controlled pattern of non-uniform doping in the APD absorbing plane. This may be done using Gas Immersion Laser doping, ion implantation or diffusion. In combination with an oppositely doped shrouding layer, the high electric field zones generated are single-photon-sensitive when elevated into an above-breakdown state by the periodic bias signal. Each of these zones is therefore able to independently support the discrete avalanche multiplication of a locally excited photocarrier. These high-field zones are coupled electrically through the shrouding layer, behaving as though wired in parallel, and the contributions to the avalanche photocurrent from photons absorbed in each of these active zones is therefore summed. A self-differencing circuit is used which compares the APD output voltage with that delayed by an integer number of gating signals. The result is that much weaker signals can be detected with a system in accordance with an embodiment of the present invention, that do not saturate the total device current. The signal generated is shown to depend upon the number of absorbed photons.

In an APD, the maximum operation speed is strongly dependent on the size of the active area. Systems in accordance with the above embodiment allow the size of the active area to be increased.

Also, errors in the measured photon number which arise due to statistical broadening with increasing photon number are reduced.

In systems in accordance with the above embodiment, no integrated circuitry is required as the device only consists of a single APD mesa, in which the active zones are joined through a single heterostructure layer and not through separate circuitry. These active zones are therefore defined in terms of the electric field distribution, rather than by an array of discrete diodes.

In systems in accordance with the above embodiment, the APD is biased periodically above the breakdown into a light sensitive state, using both AC and DC biases, the quenching being achieved passively through the gating in the low voltage part of the detector bias cycle.

The system of the above embodiment requires no quenching circuitry, electrical circuit connections between highly doped regions or reset time, it can be operated at high speed.

This high speed operation allows optical cross-talk due to the absorption of photocreated photons from adjacent highly doped areas to be suppressed. Further, electrical cross-talk is also negated due to the absence of electronic components to be mounted on the chip. The geometrical fill factor can also therefore be increased due to the fact that the electrical coupling between high electric field zones (highly doped regions) is achieved through a single semiconductor layer, and not requiring electronic components.

Also, high speed operation negates the requirements for electronics which determine when an amplification channel is saturated and therefore needs resetting.

The system of the above embodiment can be operated as a photon number resolving detector at visible/short wavelength infra-red/near infra-red wavelengths (300-3000 nm).

Systems in accordance with the above embodiment can exhibit, good photon number resolution, low crosstalk between highly doped regions which allows the regions to be closely spaced to provide a high geometric fill-factor, low dark count noise rate, low afterpulse rate, low timing jitter and a high dynamic range.

The systems may be synchronized to external clock. Further, the systems can be highly compact and use standard fabrication technology so are cheap, scalable and suitable for integration onto chips.

FIG. 7 shows the measured statistics, arising from the signal probability plotted as a function of the self-differencer output, V_{sd}.

The probability distribution is obtained from around 6 million samples, and accumulated in real-time using a fast digital oscilloscope.

Peak 701 at 0 mV corresponds to the O-photon contribution from gates in which no photon was detected.

The width of this feature (˜7 mV) is attributed to a residual component of the capacitive response of the diode, due to the imperfect cancellation of the self-differencer circuit described with reference to FIG. 3.

The feature around 53.0 mV, peak 703, is due signals arising from the absorption of one photon and peaks 705, 707 and 709 at 91.8 V, 120.0 mV and 140.4 mV respectively correspond to the detection of two, three and four photons.

The sub-linear spacing of these features is evidence that the linear dependence of the unsaturated self-differencer output of the APD on the incident photon number is influenced by the overall series resistance of the diode.

FIG. 8 shows a measured probability distribution of the output signal (grey circles) for which the 1- and 2-photons peaks, 803 and 805, are entirely separated from the 0-photon peak 801 against the self differenced output in mV.

This is achieved by tuning the arrival time of the photon with respect to the APD gate 315, the self-differencing conditions and the biases V_{dc} 311 and V_{ac} 307. The black dashed curve corresponds to a fit using Gaussians to describe each photon peak, the areas of which agree well with the Poissonian statistics of the source for the same detected photon flux.

The photon number resolution is quantified in terms of the numerical overlap between the adjacent photon number states 801, 803 and 805 and corresponds to the error in determining the incident photon number, ε_{N}, from the self differencer output, V_{sd} 333. The calculated values correspond to ε₀=2.2×10⁻⁸%, ε₁=1.1×10⁻²% and ε₂=4.3×10⁻³% for the bias conditions described.

FIG. 9 presents a greyscale image confirming the dependence of the output from a self-differencing EFD-APD photon number detector on the detected photon flux, μ.

Here, the probability is plotted coming out of the page as a function of the photon flux, μ, and the self-differencer output, V_{ad} 333.

White corresponds to high intensity and black corresponds to low intensity. The mean voltage position of the O-photon peak 901 is fixed whilst the mean positions of the 1-, 2-, 3- and 4-photon peaks (903, 905, 907 and 909 respectively) experience a weak shift to slightly lower voltage with increasing photon flux, due to sample heating caused by the increased photocurrent.

The relative intensities of the peaks, as a function of the detected photon flux, agree well with the Poissonian statistics of the source.

FIG. 10 shows the probability distribution, measured for a fixed incident photon flux, as a function of applied DC biases, V_{dc} 311 from 26.95 V to 29.35 V. It is clear that the mean voltage of the photon number peaks increases strongly with the applied DC bias 311, corresponding to enhanced separation which allows them to be fully resolved for lower N.

FIG. 11 shows the mean voltages of the 0-, 1-, 2-, 3- and 4-photon peaks as a function of the applied DC bias, V_{dc} 311, corresponding to the avalanche probability distributions shown in FIG. 10. We show that the dependence for each feature is linear, in agreement with the dependence of the electric field across the active APD junction.

FIG. 12 shows a system in accordance with a further embodiment of the present invention.

Here the electrical lines 327 and 329 of FIG. 3 are replaced with a phase shifter 1201, so as to create a phase shift of 180 degrees in one 1205 of the two outputs 1205, 1207 of the power splitter 325. The 180° phase shifter act as a signal inverter.

The signal differencer 331 of FIG. 3 is replaced with a signal combiner 1203, whose function is to add the two signals.

Since they have a relative phase shift of 180° this has the effect of cancelling the capacitive response of the APD.

This allows the detection of weak signals in a similar fashion to that described in the preceding description.

FIG. 13a shows an Avalanche Photodiode 317 mounted on a thermo-electric cooler 1307 in accordance with a further embodiment of the present invention. FIG. 13b shows the system of FIG. 13a rotated through 90°.

Thermal contact is provided to the case of the packaged device 117 through a copper heat-sink 1303 and conductive screws 1305. A temperature of T=−30° C. is commonly used.

Optical access to the sample is provided by an optical fibre pigtail 1301. The optical signal is defocused using a lens 1309, which allows the signal to be dispersed diffusively across the configuration of high-field active regions comprising the EFD-APD. Electrical access to the SiAPD, V_{apd} 315 and Vₒᵤₜ 321 is provided by metallic pins.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A photon detection system comprising an avalanche photo-diode, said avalanche photodiode comprising a p-n junction formed from a first semiconductor layer having a first conductivity type and a second semiconductor layer having a second conductivity type, wherein the first conductivity type is one selected from n-type or p-type and the second conductivity type is different to the first conductivity type and is selected from n-type or p-type, wherein the first semiconductor layer is a doped layer which is doped with dopants of a first conductivity type and where there is a variation in the concentration of dopants of the first conductivity type such that the first layer comprises islands of high field zones surrounded by low field zones, the high and low field zones distributed laterally in the plane of the p-n junction, wherein the dopant concentration is higher in the high field zones than the low field zones, said system further comprising a biasing unit, said biasing unit being configured to apply a voltage which is static in time and a time varying voltage.

2. A photon detection system according to claim 1, wherein the second layer abuts the first layer to form a p-n junction with both high field and low field zones of the first layer.

3. A photon detection system according to claim 1, wherein the high field zones have a geometric filing factor of 0.5 or more of the whole area of the p-n junction.

4. A photon detection system according to claim 1, wherein the shortest distance between adjacent high field zones is 5 μm or less.

5. A photon detection system according to claim 1, in which the high field zones are coupled electrically through the second semiconductor layer.

6. A photon detection system according to claim 1, in which the plurality of high field zones are connected by a single layer of uniform electrical potential.

7. A photon detection system according to claim 1, in which the high field zones are identical in lateral size and shape.

8. A photon detection system according to claim 1, wherein the avalanche photodiode experiences an avalanche effect when a photon pulse is received and the system further comprises a counting circuit for measuring the avalanche event in order to determine the number of photons in the received photon pulse.

9. A photon detection system according to claim 8, wherein the counting circuit comprises a discriminator configured to compare the measurement of the avalanche event with multiple predetermined levels.

10. A photon detection system according to claim 1, further comprising an output circuit configured to receive an output signal from said avalanche photodiode and process said output signal to remove a time varying component from said output signal.

11. A photon detection system according to claim 10, wherein said time varying component is cyclical and said output circuit is configured to compare the output voltage of the avalanche photodiode in one cycle with that of a preceding cycle.

12. A photon detection system according to claim 11, wherein the output circuit comprises a signal divider to split the output signal into two parts, an electrical line to delay one of parts relative to the other and a signal differencer to output the difference between the two parts.

13. A photon detection system according to claim 1, wherein the biasing circuit is configured to apply the time varying component such that it has a high part which is above the breakdown voltage of the avalanche photodiode and a low part which is below the breakdown of the avalanche photodiode and wherein the duration of the high part of the voltage component is short enough to prevent the avalanche current of the whole device saturating.

14. A photon detection system according to claim 10, where the output circuit comprises a band rejection filter.

15. A photon detection system according to claim 1, further comprising a lens and collimation optics configured to disperse the incident light uniformly across the avalanche photodiode.

16. A photon detection system according to claim 13, wherein the biasing circuit is configured to apply the high part of the time varying component is shorter than the time for the total current through the detector to saturate.

17. A method of fabricating a photon detection system, the method comprising:
forming a p-n junction by:
forming a first semiconductor layer having a first conductivity type, wherein the first semiconductor layer is a doped layer which is doped with dopants of a first conductivity type and wherein there is a variation in the concentration of dopants of the first conductivity type such that the first layer comprises islands of high field zones surrounded by low field zones, wherein the dopant concentration is higher in the high field zones than the low field zones, the high and low field zones distributed laterally in the plane of the p-n junction; and
forming a second semiconductor layer having a second conductivity type in contact with the first semiconductor layer,
the first conductivity type is one selected from n-type or p-type and the second conductivity type is different to the first conductivity type and is selected from n-type or p-type,
the method further comprising applying a voltage which is static in time and a time varying voltage across the p-n junction.

18. A method according to claim 17, wherein forming said first semiconductor layer comprises forming said high field zones using Gas Immersion Laser doping, ion implantation or diffusion to imbed material of a higher dopant concentration into a material with a lower dopant concentration.

19. A method according to claim 17, wherein forming said first semiconductor layer comprises forming said high field zones by etching pits into a semiconductor material of a first type, into which more highly doped material of the same type is deposited epitaxially.
